(19) United States
(12) Patent Application Publication
(10) Pub. No.: US 2014/0150862 A1
(43) Pub. Date: Jun. 5, 2014

(54) ASSEMBLY FOR BACK CONTACT PHOTOVOLTAIC MODULE

(71) Applicant: E I DU PONT DE NEMOURS AND COMPANY, Wilmington, DE (US)

(72) Inventors: Zelin Liu, Shanghai (CN); Minfang Mu, Shanghai (CN); Ke Yu, Shanghai (CN); Philip L. Boydell, Challex (FR)

(73) Assignee: E I DU PONT DE NEMOURS AND COMPANY, Wilmington, DE (US)

(21) Appl. No.: 14/094,865

(22) Filed: Dec. 3, 2013

(30) Foreign Application Priority Data
Dec. 4, 2012 (CN) 201210514833.3

(51) Int. Cl. H01L 31/048; H01L 31/18

(52) U.S. Cl. CPC H01L 31/0487; H01L 31/18
USPC 136/256; 438/64

(57) ABSTRACT

An assembly for forming a back-contact photovoltaic module includes an integrated back-sheet with a substrate, an electrically conductive metal circuit adhered to a front surface of the substrate, and a back insulating layer adhered to the electrically conductive metal circuit. The back insulating layer has openings aligned with the electrically conductive metal circuit and with electrical contacts on the back side of a back-contact solar cell. A front sheet and front encapsulant layer are provided on a front surface of the solar cell. The back insulating layer or the front encapsulant layer has a concave opening that complements the solar cell profile. When the back-contact solar cell is received in the concave opening, the electrical contacts on the back side of the solar cell align with the openings of the back insulating layer and with the electrically conductive metal circuit. A process for forming the described assembly is also provided.

### FIELD OF THE INVENTION

The present invention relates to back contact photovoltaic modules, and more particularly to integrated back-sheets and encapsulant assemblies for making back contact photovoltaic modules, and to processes for making back-contact photovoltaic modules with such integrated back-sheet and encapsulant assemblies.

### BACKGROUND OF THE INVENTION

A photovoltaic cell converts radiant energy, such as sunlight, into electrical energy. In practice, multiple photovoltaic cells are electrically connected together in series or in parallel and are protected within a photovoltaic module or solar module.

A photovoltaic module typically comprises, in order, a light-transmitting substrate or front sheet, an encapsulant layer, an active photovoltaic cell layer, another encapsulant layer and a back-sheet. The light-transmitting substrate is typically glass or a durable light-transmitting polymer film. The encapsulant layers adhere the photovoltaic cell layer to the front and back sheets and they seal and protect the photovoltaic cells from moisture and air and they protect the photovoltaic cells against physical damage. The encapsulant layers are typically comprised of a thermoplastic or thermosetting resin such as ethylene-vinyl acetate copolymer (EVA). The photovoltaic cell layer is any type of photovoltaic cell that converts sunlight to electric current such as single crystal silicon solar cells, polycrystalline silicon solar cells, microcrystal silicon solar cells, amorphous silicon-based solar cells, copper indium (gallium) diselenide solar cells, cadmium telluride solar cells, compound semiconductor solar cells, dye sensitized solar cells, and the like. The back-sheet provides structural support for the module, it electrically insulates the module, and it helps to protect the solar cells, module wiring and other components against the elements, including heat, water vapor, oxygen and UV radiation. The module layers need to remain intact and adhered for the service life of the photovoltaic module, which may extend for multiple decades.

Photovoltaic cells have had electrical contacts on both the front and back sides of the photovoltaic cells. However, contacts on the front sunlight receiving side of the photovoltaic cells can cause up to a 10% shading loss. In back contact photovoltaic cells, all of the electrical contacts are moved to the back side of the photovoltaic cell. With both the positive and negative polarity electrical contacts on the back side of the photovoltaic cells, electrical circuitry is needed to provide electrical connections to the positive and negative polarity electrical contacts on the back of the photovoltaic cells.

In a back contact photovoltaic module, an integrated back-sheet having patterned electrical circuitry is electrically connected to back contacts on the photovoltaic cells during lamination of the solar module. A back-sheet 10 is shown in FIG. 1a with a metal foil adhered to a surface of the back-sheet substrate 14. The metal foil, such as a copper or aluminum foil, is patterned by etching, die cutting or other processes to form one or more electrically conductive circuits 12a, 12b, 12c and 12d. As shown in FIG. 1b, an interlayer dielectric (ILD) layer 16 is formed over the foil circuits, typically by laminating or screen printing a polymeric material over the electrically conductive circuit. Openings 18 are formed in the ILD where back electrical contacts on the photovoltaic cells are to contact the foil circuits. A thermoplastic or thermosetting encapsulant sheet 20 shown in FIG. 1c, typically an EVA sheet, is placed over the ILD layer with openings formed or punched out at locations corresponding to the openings in the ILD. An electrically conductive adhesive is applied in the openings of the ILD and encapsulant layers. Back contact photovoltaic cells 22a, 22b and 22c are placed on the encapsulant layer using pick and place technology, as shown in outline form in FIG. 1d with the position of the positive and negative polarity contacts on the back side of the solar cells shown. The back contacts on the photovoltaic cells align with electrically conductive adhesive inserted in the openings in the ILD and encapsulant sheet. The back contacts on the photovoltaic cell are adhered to and electrically connected to the metal circuits on the back-sheet by the electrically conductive adhesive by heating the electrically conductive adhesive, as for example in a thermal press. The positive polarity contacts of one solar cell are electrically connected in series to the negative contacts of an adjacent solar cell by the metal circuits, as shown in FIG. 1d.

Aligning the openings of the ILD and encapsulant layers with electrically conductive circuits, inserting the electrically conductive adhesive into the aligned openings, and then aligning the openings of the back-contact solar cells with the openings in the encapsulant and ILD layers has been difficult to accomplish, especially when the solar cells that are hand placed on the back-sheet. Expansion or contraction of the encapsulant layer prior to module lamination has further complicated the electrical contact alignment with the openings in the encapsulant and ILD layers. There is a need for back-contact photovoltaic modules with integrated electrically conductive circuitry that can be produced more efficiently and consistently.

### SUMMARY OF THE INVENTION

An assembly for forming a back-contact photovoltaic module is provided. The assembly includes a substrate having aback surface and an opposite front surface, and an electrically conductive metal circuit adhered to the front surface of the substrate. A back insulating layer having first and second opposite sides is provided with the first side of the back insulating layer adhered to the electrically conductive metal circuit. The back insulating layer has a plurality of openings passing through the back insulating layer and that are aligned with the electrically conductive metal circuit.

The assembly includes a back-contact solar cell with a front light-receiving side, an opposite back side with a plurality of electrical contacts formed on the back side of said back-contact solar cell. The back side of the solar cell faces the back insulating layer. The back-contact solar cell has a side edge between the front side and back side of the solar cell that defines a profile of the solar cell.

The assembly includes a front encapsulant layer having opposite first and second sides, with first side of the front encapsulant layer facing the light-receiving front side of the back-contact solar cell. A transparent front sheet abuts the second side of the front encapsulant layer.

In the assembly, at least one of the second side of the back insulating layer and the first side of the front encapsulant layer has a concave opening formed thereon that complements the profile of the back-contact solar cell such that the back-contact solar cell fits into the concave opening. When the back-contact solar cell is received in the concave opening, the electrical contacts on the back side of the back-contact solar cell align with the openings passing through the back insulating layer and with the electrically conductive metal circuit.

A process for forming the described assembly for forming a back-contact photovoltaic module is also provided.

### BRIEF DESCRIPTION OF THE DRAWINGS

The detailed description will refer to the following drawings which are not drawn to scale and wherein like numerals refer to like elements:

FIGS. 1a-1c are plan views of a conventional integrated back sheet assembly for a back-contact photovoltaic module;

FIG. 1d shows the position of back-contact solar cells placed over the back sheet assembly of FIG. 1c with the locations of the backside electrical contacts shown.

FIG. 2 is a cross-sectional view of a substrate with an electrically conductive metal circuit adhered thereon.

FIGS. 3a and 3b are cross-sectional views showing steps in the formation of the disclosed integrated back-sheet for back-contact photovoltaic modules.

FIG. 4 is a cross-sectional view showing a further step in the formation of the disclosed integrated back-sheet for back-contact photovoltaic module modules.

FIG. 5 is a perspective view of a die cutting mold for producing the integrated back-sheet shown in FIG. 4.

FIG. 6 is a cross-sectional view showing a further step in the formation of the disclosed integrated back-sheet for back-contact photovoltaic modules.

FIG. 7 is a perspective view of a die cutting mold for producing the integrated back-sheet shown in FIG. 6.

FIG. 8 is a perspective view of an alternative die cutting mold for producing the integrated back-sheet shown in FIG. 6.

FIG. 9 is a cross-sectional view of one embodiment of the disclosed back-contact photovoltaic assembly.

FIG. 10 is a cross-sectional view of an alternative embodiment of the disclosed back-contact photovoltaic assembly.

FIG. 11 is a cross-sectional view of an alternative embodiment of the front portion of a disclosed back-contact photovoltaic assembly.

### DETAILED DESCRIPTION OF THE INVENTION

To the extent permitted by the applicable patent law, all publications, patent applications, patents, and other references mentioned herein are incorporated by reference in their entirety.

The materials, methods, and examples herein are illustrative only and the scope of the present invention should be judged only by the claims.

### DEFINITIONS

The following definitions are used herein to further define and describe the disclosure.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

As used herein, the terms “a” and “an” include the concepts of “at least one” and “one or more than one”.

Unless stated otherwise, all percentages, parts, ratios, etc., are by weight.

When the term “about” is used in describing a value or an end-point of a range, the disclosure should be understood to include the specific value or end-point referred to.

As used herein, the terms “sheet”, “layer” and “film” are used in their broad sense interchangeably. A “frontsheet” is a sheet, layer or film on the side of a photovoltaic module that faces a light source and may also be described as an incident layer. Because of its location, it is generally desirable that the frontsheet has high transparency to the desired incident light. A “back-sheet” is a sheet, layer or film on the side of a photovoltaic module that faces away from a light source, and is generally opaque. In some instances, it may be desirable to receive light from both sides of a device (e.g., a bifacial device), in which case a module may have transparent layers on both sides of the device.

“Encapsulant” layers are used to encase the fragile voltage-generating photoactive layer, to protect it from environmental or physical damage, and hold it in place in the photovoltaic module. Encapsulant layers may be positioned between the solar cell layer and the front incident layer, between the solar cell layer and the back-sheet, or both. Suitable polymer materials for the encapsulant layers typically possess a combination of characteristics such as high transparency, high impact resistance, high penetration resistance, high moisture resistance, good ultraviolet (UV) light resistance, good long term thermal stability, good long term weatherability, and adequate adhesion strength to frontsheets, back-sheets, other rigid polymeric sheets and solar cell surfaces.

As used herein, the terms “photoactive” and “photovoltaic” may be used interchangeably and refer to the property of converting radiant energy (e.g., light) into electric energy.

As used herein, the terms “photovoltaic cell” or “photoactive cell” or “solar cell” mean an electronic device that converts radiant energy (e.g., light) into an electrical signal. A photovoltaic cell includes a photoactive material layer that may be an organic or inorganic semiconductor material that is capable of absorbing radiant energy and converting it into electrical energy. The terms “photovoltaic cell” or “photoactive cell” or “solar cell” are used herein to include photovoltaic cells with any types of photoactive layers including, crystalline silicon, polycrystalline silicon, microcrystal silicon, and amorphous silicon-based solar cells, copper indium (gallium) diselenide solar cells, cadmium telluride solar cells, compound semiconductor solar cells, dye sensitized solar cells, and the like.

As used herein, the term “photovoltaic module” or “solar module” or “solar cell module” (also “module” for short) means an electronic device having at least one photovoltaic cell protected on one side by a light transmitting front sheet and protected on the opposite side by an electrically insulating protective back-sheet.

As used herein, terms “die-cut” and “die-cutting” refer to a manufacturing process wherein one or more blades of a desired shape slice through one or more layers of a material such as wood, plastic, paper, metal or fabric to produce cut shapes of material, and includes die-cutting done on flat, rotary or multiple-step presses, as well as die-cutting by laser.

Disclosed herein is an integrated back-sheet and assembly for a back-contact photovoltaic module, processes for forming such an assembly, back-contact photovoltaic modules made with such an integrated back-sheet and assembly, and processes for forming such back-contact photovoltaic modules.

The disclosed integrated back-sheet includes a substrate. The substrate has a back surface and a front surface, wherein the front surface faces to the light source when in in use. The substrate may be comprised of inorganic materials, organic materials, or combinations of inorganic and organic materials. Suitable inorganic materials that may be used in forming the substrate include, without limitation, metallic materials (such as aluminium foil, aluminium panel, copper, steel, alloy, stainless steel, etc.), non-metallic inorganic materials (such as amorphous materials (e.g., glass) and crystalline materials (e.g., quartz)), inorganic compounds, ceramics, and minerals (such as mica or asbestos). Preferably, the substrate is comprised of polymeric materials, optionally in conjunction with other materials used in photovoltaic back-sheets. The substrate may comprise a polymer film, sheet or laminate that is used as a back-sheet in conventional photovoltaic modules. The substrate may, for example, be comprised of film comprised of one or more of polyester, fluoropolymer, polycarbonate, polypropylene, polyethylene, cyclic polyloefin, acrylic, cellulose acetate, acrylate polymer such as polymethylmethacrylate (PMMA), polystyrene, styrene-acrylate copolymers, acrylonitrile-styrene copolymers, poly(ethylene naphthalate), polyethersulfone, polysulfone, polyamide, epoxy resin, glass fiber reinforced polymer, carbon fiber reinforced polymer, vinyl chloride polymers, polyvinylidene chloride, vinylidene chloride copolymers, and the like. The substrate of the integrated back-sheet may also comprise laminates of such polymer films. The layers of such laminates may be adhered to each other by adhesives between the layers or by adhesives incorporated into one or more of the laminate layers.

Laminates of polyester films and fluoropolymer are especially suitable for the substrate. Suitable polyesters include polyethylene terephthalate (PET), polytrimethylene terephthalate, polybutylene terephthalate, polyhexamethylene terephthalate, polyethylene phthalate, polytrimethylene phthalate, polybutylene phthalate, polyhexamethylene phthalate or a copolymer or blend of two or more of the above. Suitable fluoropolymers include polyvinylfluoride (PVF), polyvinylidene fluoride, polytetrafluoroethylene, ethylene-tetrafluoroethylene copolymers and combinations thereof. In one embodiment, the substrate comprises a bi-axially oriented PET film adhered to a PVF film. In another embodiment, the substrate comprises polyester film with fluoropolymer films adhered to the opposite sides of the polyester film. Alternatively, the substrate may comprise a single layer polymer sheet such as a synthetic rubber or polyolefin-based sheet.

There are no specific restrictions on the thickness of the substrate or on the various layers of the substrate. Thickness varies according to specific application. In one preferred embodiment, the substrate comprises a fluoropolymer layer with a thickness in the range of 20-50 μm adhered to a PET film with a thickness of 50-300 μm.

Various known additives and fillers may be added to the layer(s) of the substrate to satisfy various different requirements. Suitable additives may include, for example, light stabilizers, UV stabilizers and absorbers, thermal stabilizers, anti-hydrolytic agents, light reflection agents, flame retardants, pigments, titanium dioxide, dyes, slip agents, calcium carbonate, silica, and reinforcement additives such as glass fibers and the like. There are no specific restrictions to the content of the additives and fillers in the substrate layers as long as the additives do not produce an undue adverse impact on the substrate layers or their adhesion to other layers of the substrate or to the adhesion of the substrate to the electrically conductive metal circuit.

The polymeric films or sheets of the substrate may include one or more non-polymeric layers or coatings such as a metallic, metal oxide or non-metal oxide surface coating. Such coatings are helpful for reducing moisture vapor transmission through a back-sheet structure. The thickness of such a metallic, metal oxide layer or non-metal oxide layer on one or more of the polymer films typically measures between 50 Å and 4000 Å, and more typically between 100 Å and 1000 Å, but may be up to 50 um thick.

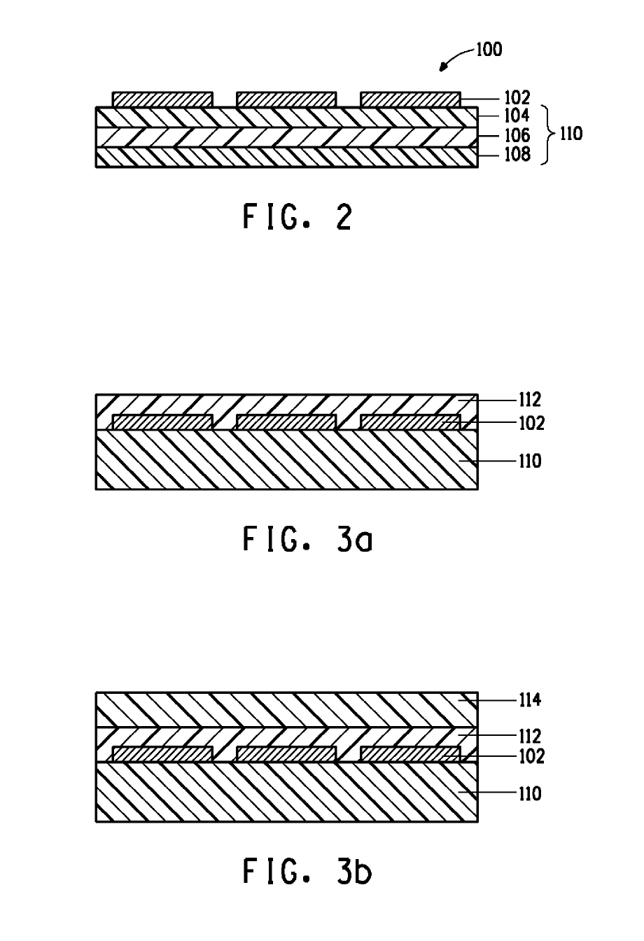

In the embodiment shown in FIG. 2, a substrate 110 is comprised of multiple layers. The layers preferably comprise polymer film layers and one or more adhesive layers. In the embodiment shown in FIG. 2, the substrate 110 comprises an outer polymer layer 108, an adhesive layer 106, and another polymer layer 104. Typically, the outer polymer layer 108 comprises a durable polymer film such as a fluoropolymer film as described above. The adhesive layer 106 may comprise, without limitation, reactive adhesives (e.g., polyurethane, acrylic, epoxy, polyimide, or silicone adhesives) and non-reactive adhesives (e.g., polyethylenes (including ethylene copolymers) or polyesters). The polymer layer 104 is preferably another polymer film with good moisture barrier and electrical insulation properties such as a polyester film as described above.

The disclosed integrated back-sheet further includes an electrically conductive metal circuit adhered to the substrate. The electrically conductive metal circuit may be any type of circuit such as a printed metal circuit or a circuit formed from a metal foil adhered to the substrate and etched, die-cut or otherwise formed into one or more patterned electrically conductive circuits. Where the electrically conductive metal circuit is formed from a metal foil, the foil is preferably an electrically conductive metal foil such as foil of aluminum, tin, copper, nickel, silver, gold, tin coated copper, silver coated copper, gold coated copper, steel, invar, and alloys thereof. Aluminum foil and copper foil are most commonly selected on the basis of cost and other factors. The thickness of the foil may be in the range of 5-50 μm, or preferably 8-40 μm. Examples of suitable foils include a 30 μm thick copper foil (type: THE-T9FB) from Suzhou Fukuda Metal Co., Ltd of Suzhou, China, and a 30 μm thick MHT copper foil from OAK-MITSUI LLC, of Hoosick Falls, N.Y., USA. The metal foil may be adhered to the substrate by an adhesive such as an extruded thermoplastic adhesive. Preferred thermoplastic adhesives include ethylene copolymers, acrylic polymers and copolymers, polymethyl methacrylate, polyesters, and blends of such polymers. As shown in FIG. 2, the electrically conductive metal circuit 102 is attached to the polymer layer 104 of the substrate.

The disclosed integrated back-sheet also comprises a back insulating layer with first and second opposite sides, wherein the first side of the back insulating layer is adhered to the electrically conductive metal circuit. The back insulating layer may be comprised of any suitable inorganic materials, organic materials, or combinations of inorganic and organic materials. Suitable inorganic materials that may comprise the back insulating layers include, without limitation, non-metallic inorganic materials (such as amorphous materials (e.g., glass) or crystalline materials (e.g., quartz)), inorganic compounds, ceramics, and minerals (such as mica or asbestos). Preferably, the back insulating layer is comprised of a polymer that will adhere the electrically conductive metal circuit to the back side of a back-contact solar cell. The back insulating layer is preferably comprised of polymer that remains very viscous at typical photovoltaic module lamination temperatures of 120 to 180° C., and more preferably 125 to 160° C. For example, a thermoplastic polymer with a melt flow rate of in the range of 0 to 100 g/10 min (test condition: 190° C./2.16 kg), and more preferably 0 to 50 g/10 min (test condition: 190° C./2.16 kg) serves well as the back insulating layer because such a polymer remains sufficiently viscous during module thermal lamination so that the back insulating layer holds the photovoltaic cells in a fixed position throughout the module lamination.

The back insulating layer may be formed of a polymer used as an encapsulant material in photovoltaic modules. The back insulating layer may, for example, be a film or sheet comprising, without limitation, polyolefins, poly(vinyl butyral) (PVB), polyurethane (PU), polyvinylchloride (PVC), acid copolymers, silicone elastomers, epoxy resins, or a combination thereof. Suitable polyolefins include, without limitation, polyethylenes, ethylene vinyl acetates (EVA), ethylene acrylate copolymers (such as poly(ethylene-co-methyl acrylate) and poly(ethylene-co-butyl acrylate)), ionomers, polyolefin block elastomers, and the like. Exemplary PVB based materials include, without limitation, DuPont™ PV5200 series encapsulant sheets. Exemplary ionomer based materials include, without limitation, DuPont™ PV5300 series encapsulant sheets and DuPont™ PV5400 series encapsulant sheets from DuPont. Another exemplary polyolefin for the polymeric layer is metallocene-catalyzed linear low density polyethylenes. The back insulating layer may include cross-linking agent that promotes cross-linking upon heating so that the polymer layer remains very viscous throughout the thermal lamination of the module.

The back insulating layer may be comprised of an extruded or cast thermoplastic polymer layer. Thermoplastic ethylene copolymers that can be utilized for the back insulating layer include the ethylene copolymers disclosed in PCT Patent Publication No. WO2011/044417. Preferred ethylene copolymers are comprised of ethylene and one or more monomers selected from the group of consisting of C1-4 alkyl acrylates, C1-4 alkyl methacrylates, methacrylic acid, acrylic acid, glycidyl methacrylate, maleic anhydride and copolymerized units of ethylene and a comonomer selected from the group consisting of C4-C8 unsaturated anhydrides, monoesters of C4-C8 unsaturated acids having at least two carboxylic acid groups, diesters of C4-C8 unsaturated acids having at least two carboxylic acid groups and mixtures of such copolymers, wherein the ethylene content in the ethylene copolymer preferably accounts for 60-90% by weight. The ethylene copolymer used in the back insulating layer may include a copolymer of ethylene and another α-olefin. The ethylene content in the copolymer may account for 60-90% by weight, preferably accounting for 65-88% by weight, and ideally accounting for 70-85% by weight of the ethylene copolymer. The other comonomer(s) preferably constitute 10-40% by weight, more preferably accounting for 12-35% by weight, and ideally accounting for 15-30% by weight of the ethylene copolymer. The ethylene copolymer layer is preferably comprised of at least 70 weight percent of the ethylene copolymer. The ethylene copolymer may be blended with up to 30% by weight, based on the weight of the polymeric layer, of other thermoplastic polymers such as polyolefins, as for example linear low density polyethylene, in order to obtain desired properties. Ethylene copolymers are commercially available. For example, one may be purchased from DuPont under the trade-name Bynel®.

The back insulating layer may further contain any additive or filler known within the art. Such exemplary additives include, but are not limited to, plasticizers, processing aides, flow enhancing additives, lubricants, pigments, dyes, flame retardants, impact modifiers, nucleating agents to increase crystallinity, antiblocking agents such as silica, thermal stabilizers, hindered amine light stabilizers (HALS), UV absorbers, UV stabilizers, anti-hydrolytic agents, light reflection agents, pigments, titanium dioxide, dyes, slip agents, calcium carbonate, dispersants, surfactants, chelating agents, coupling agents, adhesives, primers, reinforcement additives, such as glass fiber, fillers and the like. There are no specific restrictions to the content of the additives and fillers in the back insulating layer as long as the additives do not produce an undue adverse impact on the back insulating layer or its adhesion to the electrically conductive metal circuit or the substrate.

In the embodiment shown in FIG. 3a, the back insulating layer comprises a polymer layer 112 that is applied, extruded or cast over the electrically conductive metal circuit 102. The polymer layer 112 may, for example, be an extruded polymer layer that is extruded over the electrically conductive metal circuit 102 and compressed against the electrically conductive metal circuit 102 and the underlying substrate 110 using a compression roller or press. Alternatively, the back insulating layer may be applied as a film and thermally pressed against the electrically conductive metal circuit 102 and the underlying substrate 110 using a roller or press. The polymer layer 112 preferably has a thickness in the range of 5 to 2000 μm and more preferably within the range of 50 to 500 μm. The polymer layer 112 may be comprised of a polymer with adhesive properties that allow it to adhere directly to the electrically conductive metal circuit 102 and substrate 110, or another adhesive, such as a polyurethane adhesive, may be applied between the polymer layer 112 and the electrically conductive metal circuit 102 and between the polymer layer 112 and the substrate 110.

In the embodiment shown in FIG. 3b, the back insulating layer further comprises a further polymer layer 114 that is applied or extruded over the polymer layer 112. The polymer layers 112 and 114 may be comprised of one or more of the polymers discussed above with regard to the back insulating layer. For example, the further polymer layer 114 may be an extruded ethylene copolymer layer that is extruded over the polymer layer 112 and compressed against the polymer layer 112 using a compression roller. Alternatively, the polymer layers 112 and 114 may be applied as thermoplastic films and thermally pressed against the electrically conductive metal circuit 102 and the underlying substrate 110. The further polymer layer 114 preferably has a thickness in the range of 5 to 4000 μm and more preferably within the range of 50 to 1000 μm. The further polymer layer 114 may be comprised of a polymer with adhesive properties that allow it to adhere directly to the polymer layer 112 or another adhesive, such as a polyurethane adhesive, may be applied between the further polymer layer 114 and the polymer layer 112. In a preferred embodiment, the adhesion or peel strength between the polymer layer 112 and the electrically conductive metal circuit 102 and the substrate 110 is greater than the adhesion or peel strength between the polymer layer 112 and the further polymer layer 114. When pressure sensitive adhesive (for example, acrylic-based adhesive) is used to adhere the polymer layers 114 and 112, the bonding strength of the adhesive can be tuned by applying adhesive products with different average molecule weight or different Tg. When extruded tie layers are used to adhere different layers, a higher extrusion temperature can be used to achieve a higher bonding strength. Where the polymer layers 114 and 112 are extruded, different bonding strengths can be obtained by using different extrusion temperatures.

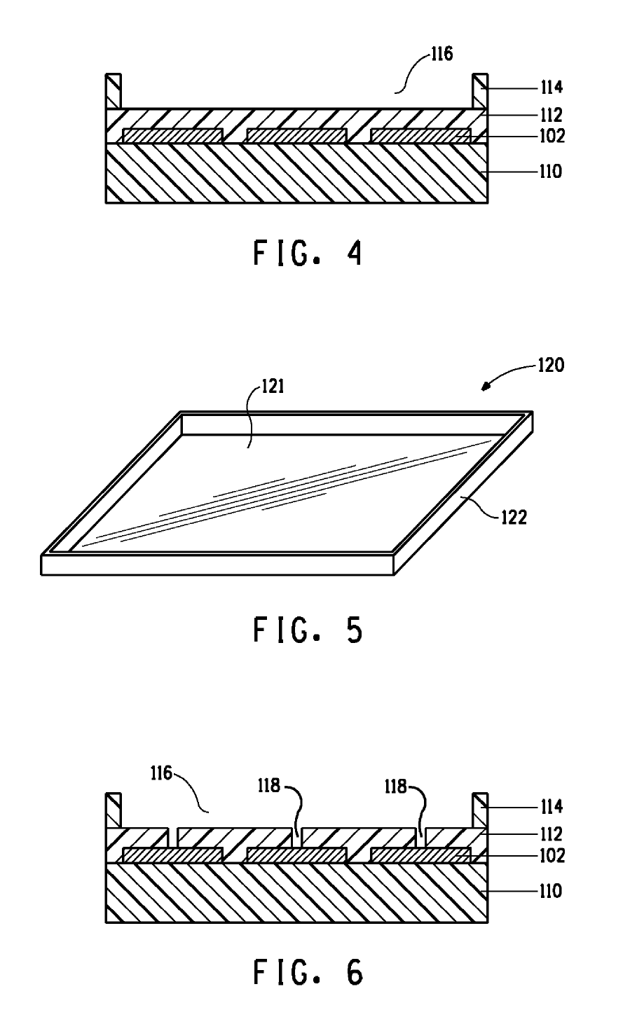

In the embodiment shown in FIG. 4, the further polymer layer 114 is die cut to form one or more concave recessed openings 116 that each have a shape that substantially corresponds to the profile of a back contact solar cell. The concave opening(s) 116 may be formed using one or more flat die cutting molds like the mold 120 shown in FIG. 5. The mold 120 has a flat substrate 121 with a peripheral cutting edges 122 attached to the substrate 121. Multiple die cutting molds like the mold 120 may be connected to form multiple recessed openings in the further polymer layer 114 wherein each opening is sized to accommodate a solar cell of corresponding dimensions. The mold is preferably made of metal, fiberglass, a rigid plastic, a composite or some combination thereof. One preferred material for the mold 124 is steel. Alternatively, recessed openings can be formed in the further polymer layer 114 using a rotary die cutting device or other such device such as a calendar roll. The recessed openings 116 are formed by first cutting the desired shapes in the further polymer layer 114, and them peeling the cut portions from each of the cut shapes so as to leave the openings 116 with dimensions that correspond to the profile of back-contact solar cells to be used in the photovoltaic module.

The back insulating layer has a plurality of openings that pass through the back insulating layer and are aligned with the electrically conductive metal circuit. The openings in the back insulating layer are preferably cut and removed by a die-cutting mold or roll.

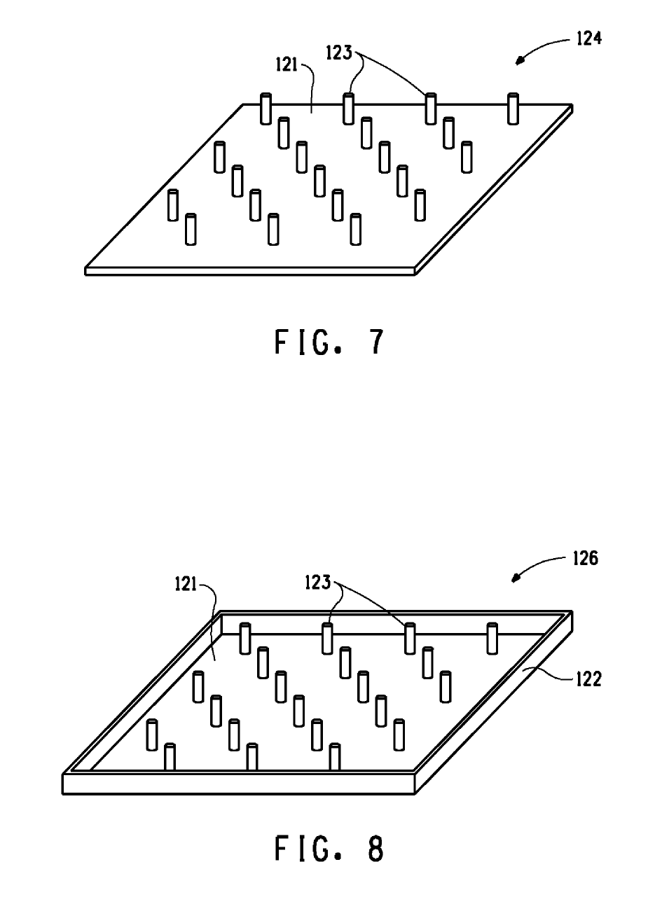

After the solar cell shaped concave openings 116 are formed in the further polymer layer 114, a plurality of individual openings 118 are formed in the polymer layer 112 using a die cutting mold or roll like the mold 124 shown in FIG. 7. The openings 118 in the polymer layer 112 may be formed using a flat and rigid die cutting mold like the mold 124 shown in FIG. 7. The mold 124 is formed of a flat plate 121 with a plurality of open ended cutting blanks 123. The cutting blanks 123 are shown with a cylindrical cross section in FIG. 7, but other cross-sectional cutting shapes such as ovals or squares can be used to cut openings in the back insulating layer. The cutting blanks are arranged on the plate 121 in a pattern corresponding to the location of back contacts on the back side of a solar cell and to the electrically conductive metal circuit to which the solar cell back contacts are to be connected. In a preferred process for forming the openings 118 in the polymer layer 112, the mold is pressed against the polymeric layer and then withdrawn along with the polymeric material in the mold blanks so as to form the openings 118 in the polymer layer 112. The mold is preferably made of metal, fiberglass, a rigid plastic, a composite or some combination thereof. One preferred material for the mold 124 is steel. The openings in the back insulating layer may alternatively be formed by a rotary die cutting process or other such cutting process such as by a calendaring process.

An alternative die-cutting mold 126 is shown in FIG. 8 that combines the flat die cutting mold 120 of FIG. 5 and the mold of FIG. 7 with individual die cutting blanks 123. The die cutting mold shown in FIG. 8 can be used to cut both the concave solar cell size opening(s) 116 in the further polymer layer 114, and the individual openings 118 in the polymer layer 112 in a single step. Preferably the mold 126 removes the polymeric material from both solar cell shaped portion of the further polymer layer 114 and the individual openings 118 from the polymer layer 112 when the mold is withdrawn from the polymer layers 114 and 112.

An electrically conductive adhesive is inserted or injected into the individual openings 118 prior to the introduction of a back-contact solar cell into the concave opening 116. The electrically conductive adhesive is preferably thermally cured for dimensional stability during normal vacuum thermal lamination of the photovoltaic module, and may be an electrically conductive adhesive such as Loctite 3888 or Loctite 5421 from Henkel Corporation, of Germany.

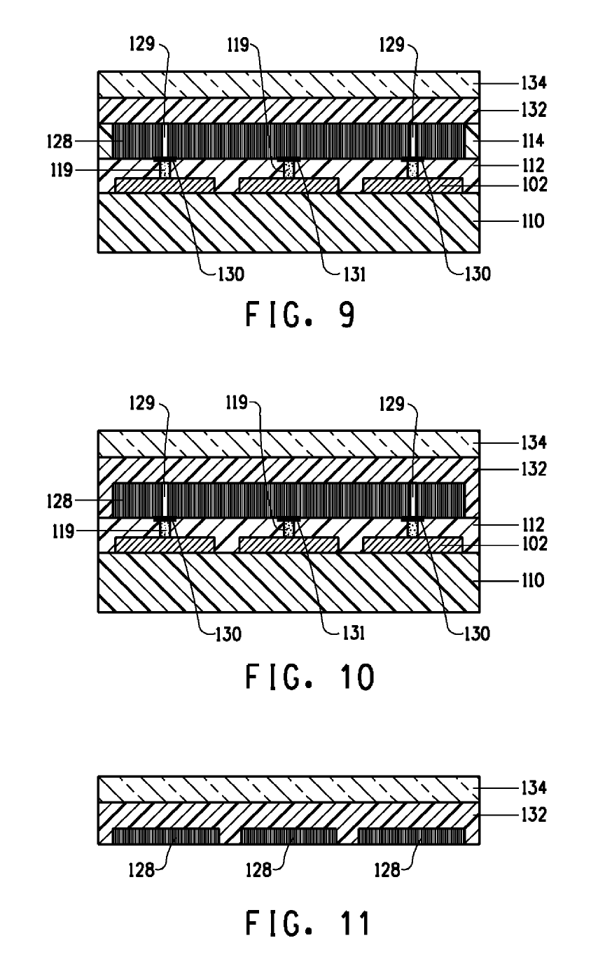

The disclosed assembly for a back-contact photovoltaic module comprises one or more back-contact solar cells aligned over the back insulating layer of the integrated back-sheet. A back-contact solar cell 128, as can be seen in FIG. 9, has positive and negative polarity electrical contacts on its back side. The back contacts 130 electrically connect to the front side of the solar cell through vias 129 in the solar cell. The back contacts 131 electrically connect to the back side of the solar cell. The back contacts 130 and 131 on the back side of the solar cell align with the openings 118 in the polymer layer 112 when the solar cell is inserted into the concave opening 116 in the further polymer layer 114.

In the disclosed assembly, a front encapsulant layer 132 is arranged over the front side of the solar cell(s) 128 and a transparent front sheet 134, such as a glass or polymer front sheet is placed over the front encapsulant layer. A typical glass type front sheet is 90 mil thick annealed low iron glass. The front encapsulant layer 132 may be comprised of any of the polymers described above with regard to the back insulating layer. The front encapsulant layer may, for example, be a film or sheet comprising polyolefins, poly(vinyl butyral) (PVB), polyurethane (PU), polyvinylchloride (PVC), acid copolymers, silicone elastomers, epoxy resins, or a combination thereof, including polyethylenes, ethylene vinyl acetates (EVA), ethylene acrylate copolymers, ionomers, polyolefin block elastomers, and the like. The front encapsulant layer 132 may include cross-linking agent that promotes cross-linking upon heating so that the polymer layer remains very viscous throughout the thermal lamination of the module.

After lay-up of the photovoltaic module components is complete, as shown in FIG. 9, the assembly is laminated in a press with the application of heat and pressure to form the disclosed back-contact photovoltaic module. The back-contact photovoltaic module may be produced through autoclave or non-autoclave processes. For example, the assembly constructs described above may be laid up in a vacuum lamination press and laminated together under vacuum with heat and standard atmospheric or elevated pressure. The assembly is laminated under heat and pressure and a vacuum (for example, in the range of about 27-28 inches (689-711 mm) Hg) to remove air. In an exemplary procedure, the laminate assembly of the present invention is placed into a bag capable of sustaining a vacuum (“a vacuum bag”), the air is drawn out of the bag using a vacuum line or other means of pulling a vacuum on the bag, the bag is sealed while maintaining the vacuum, the sealed bag is placed in an autoclave at a temperature of about 120° C. to about 180° C., at a pressure of about 200 psi (about 15 bars), for from about 10 to about 50 minutes. Preferably the bag is autoclaved at a temperature of from about 120° C. to about 160° C. for 20 minutes to about 45 minutes. More preferably the bag is autoclaved at a temperature of from about 135° C. to about 160° C. for about 20 minutes to about 40 minutes.

Air trapped within the laminate assembly may be removed through a nip roll process. For example, the laminate assembly may be heated in an oven at a temperature of about 80° C. to about 120° C., or preferably, at a temperature of between about 90° C. and about 100° C., for about 30 minutes. Thereafter, the heated laminate assembly may be passed through a set of nip rolls so that the air in the void spaces between the photovoltaic module outside layers, the photovoltaic cell layer and the encapsulant layers may be squeezed out, and the edge of the assembly sealed. This process may provide the final photovoltaic module laminate or may provide what is referred to as a pre-press assembly, depending on the materials of construction and the exact conditions utilized.

The pre-press assembly may then be placed in an air autoclave where the temperature is raised to about 120° C. to about 160° C., or preferably, between about 135° C. and about 160° C., and the pressure is raised to between about 100 psig and about 300 psig, or preferably, about 200 psig (14.3 bar). These conditions are maintained for about 15 minutes to about 1 hour, or preferably, about 20 to about 50 minutes, after which, the air is cooled while no more air is added to the autoclave. After about 20 minutes of cooling, the excess air pressure is vented and the photovoltaic module is removed from the autoclave. The described lamination process should not be considered limiting. Essentially, any photovoltaic module lamination process known within the art may be used to produce the back-contact photovoltaic modules with the integrated back-sheet and the assembly as disclosed herein.

An alternative embodiment is show in FIGS. 10 and 11. In this embodiment, the back insulating layer is a single flat polymer layer 112 that is applied or extruded over the electrically conductive metal circuits 102. The polymer layer 112 in the embodiment shown in FIG. 10 preferably has a thickness in the range of 5 to 4000 μm and more preferably within the range of 50 to 1000 μm. The polymer layer 112 may be comprised of a polymer with adhesive properties that allows it to adhere directly to the electrically conductive metal circuit 102 and the substrate 110 or an adhesive, such as a polyurethane adhesive, may be applied between the polymer layer 112 and the electrically conductive metal circuit 102 and substrate 110. Individual holes corresponding to the location of the solar cell back contacts, like the holes 118 shown in FIG. 6, are formed in the polymer layer 112 by one of the processes described above with regard to FIG. 6. A concave opening like the opening 116 shown in FIG. 6 is not formed over the back insulating layer. Rather, the positioning of the solar cells and the solar cell back contacts relative to the holes in the back insulating layer is set by providing a concave opening on the solar cell facing side of the front encapsulant layer 132. In the embodiment shown in FIGS. 10 and 11, it is important that the front encapsulant layer be comprised of polymer that remains very viscous at typical photovoltaic module lamination temperatures of 120 to 180° C., and more preferably 125 to 160° C. The front encapsulant layer must remain sufficiently viscous during module thermal lamination so that it holds the photovoltaic cells in a fixed position throughout the module lamination. The polymers described above with regard to the back polymeric layer can be made to serve this function.

One or more concave openings on the side of the front encapsulant layer 132 that faces the solar cell are dimensioned to correspond to the profile of the back-contact solar cells. FIG. 11 shows an embodiment in which multiple solar cells 128 are received within concave openings formed in the front encapsulant layer 132. Concave openings may be formed on the front encapsulant layer by much the same process as used to form the concave opening 116 in the back insulating layer as shown in FIGS. 4 and 6. The front encapsulant layer 132 comprises a first sublayer adhered to the transparent front sheet 134 and a second sublayer adhered to the first sublayer. The adhesion between the first sublayer and the front sheet is made greater than the adhesion between the first sublayer and the second sublayer of the front encapsulant layer. The concave openings are formed in the second sublayer of the front encapsulant layer by cutting the second sublayer in shapes corresponding to the profile of solar cells, as for example by die cutting, and peeling the cut sections of the second sublayer of the front encapsulant layer from the first sublayer. When a back-contact solar cell is placed by hand or by machine into the concave opening of the front encapsulant layer 132 and the front encapsulant layer 132 is subsequently aligned over the back insulating layer during the lay-up of the module, the solar cell back contacts 130 and 131 are put into alignment over the holes in the back insulating layer containing electrically conductive adhesive 119 and over the electrically conductive metal circuits 102 on the substrate 110. After lay-up of the photovoltaic module components is complete, as shown in FIG. 10, the assembly may be laminated in a vacuum press with the application of heat and pressure as described above with regard to the module assembly of FIG. 9.

In the disclosed embodiments, cost effective registration of back-contact solar cells is made possible, regardless of whether the cells are placed by machine or by hand. Openings in the back insulating layer are quickly and easily aligned with the electrical contacts on the back side of back-contact solar cells and with the electrically conductive metal circuit integrated with the substrate. The disclosed embodiments provide a back-contact photovoltaic module with integrated back-sheets that can be produced more efficiently and consistently.

### EXAMPLES

The following Examples are intended to be illustrative of the present invention, and are not intended in any way to limit the scope of the present invention.

### Materials Used in Examples

PET film: Corona treated (both sides) Melinex™ S polyethylene terephthalate film (188 and 250 microns thicknesses) with a density equal to 1.40 g/cm³ obtained from DuPont Teijin Films (U.S.A.);

Ethylene acrylate copolymer resin: Bynel® 22E757 modified ethylene acrylate copolymer resin obtained from DuPont with a density equal to 0.94 g/cm³, an MFI equal to 8.0 g/10 min, and a melting point equal to 92° C.;

Ethylene methacrylic acid copolymer: Nucrel® 0910 copolymer of ethylene and methacrylic acid, made with 9 wt % methacrylic acid, and with a density equal to 0.93 g/cm³, an MFI equal to 10.0 g/10 min, and a melting point equal to 100° C.;

Ethylene-vinyl acetate copolymer resin: Elvax® PV 1650Z extrudable ethylene-vinyl acetate copolymer resin obtained from DuPont obtained from DuPont with a density equal to 0.96 g/cm³, an MFI equal to 31 g/10 min, and a melting point equal to 61° C.

PVF film: Tedlar® polyvinyl fluoride oriented film with a thickness of 38 microns obtained from DuPont.

Adhesive: polyurethane adhesive (PP-5430 and A50) obtained from Mitsui.

Aluminium (Al) foil: 20 micron thick aluminium foil obtained from Shanghai Huxin Aluminum Foil Co., Ltd. of Shanghai, China.

Copper (Cu) foil: 35 micron thick copper foil obtained from Suzhou Fukuda Metal Co., Ltd. of Suzhou, China.

### Test Methods

Peel Test Method

Peel strength is a measure of adhesion of laminated samples. Peel strength is measured according to the ASRM D1876 Standard and is expressed in units of N/cm. For example, when the peel strength was tested between a metal foil and a polymer substrate, the metal foil/thermoplastic adhesive/polymer substrate laminate was cut into sample strips of 2.54 cm in width and 10 cm in length, and the thermoplastic adhesive layer and the substrate were fixed respectively in the upper and lower grips of an extension meter to carry out a peeling test at a speed of 5 in/min (12.7 cm/min).

### Sample Preparation

Preparation of Circuit Back-Sheet

The metal foil was laminated to a substrate by an extruded tie layer, and then was cut through die cutting to make patterned circuit. A 188 micron-thick Melinex™ S PET film was corona treated on both sides. A 38 micron-thick Tedlar® oriented PVF film obtained from DuPont was adhered to one side of the PET film using a 10 micron thick layer of Mitsui PP-5430 polyurethane adhesive. On an extrusion-lamination machine manufactured by Davis Standard, a 1:1 (w/w) blend of Bynel® 22E757 ethylene methyl acrylate copolymer from DuPont and Nucrel® 0910 copolymer ethylene and methacrylic acid resin from DuPont was extruded at an extrusion temperature of 285° C. between the metal foil and the side of the PET film opposite of the PVF film to form a tie layer adhesive film with a thickness of about 100 microns.

The substrate structure, metal foil, tie layer formulation, and process temperature are summarized in Table 1.

TABLE 1

| | | | | Extrusion |
|---|---|---|---|---|
| | | | | temperature |
| Sample | Substrate | Metal foil | Tie layer | (° C.) |
| TPCu | Tedlar ®/ | Cu foil | Bynel ® 22E757 (50%) | 285 |
| | PET | | Nucrel ® 0910 (50%) | |
| TPAl | Tedlar ®/ | Al foil | Bynel ® 22E757 (50%) | 285 |
| | PET | | Nucrel ®0910 (50%) | |

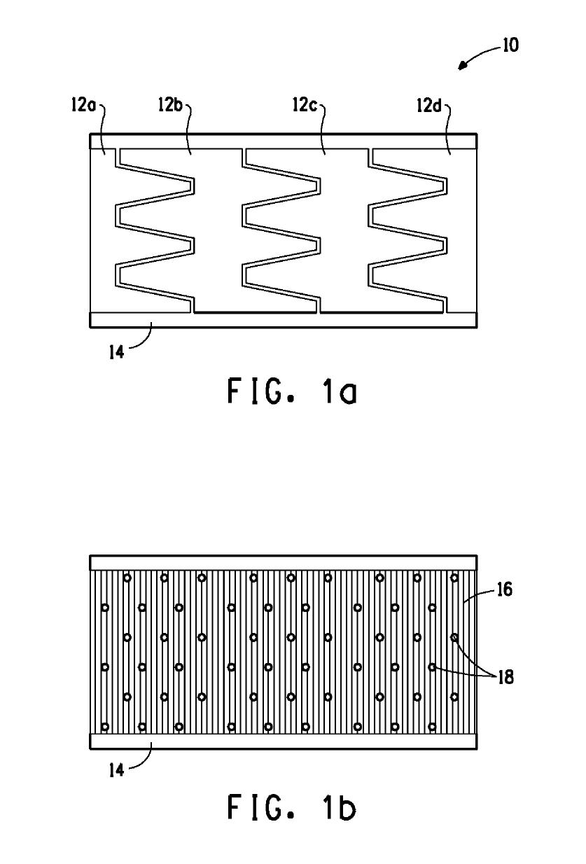

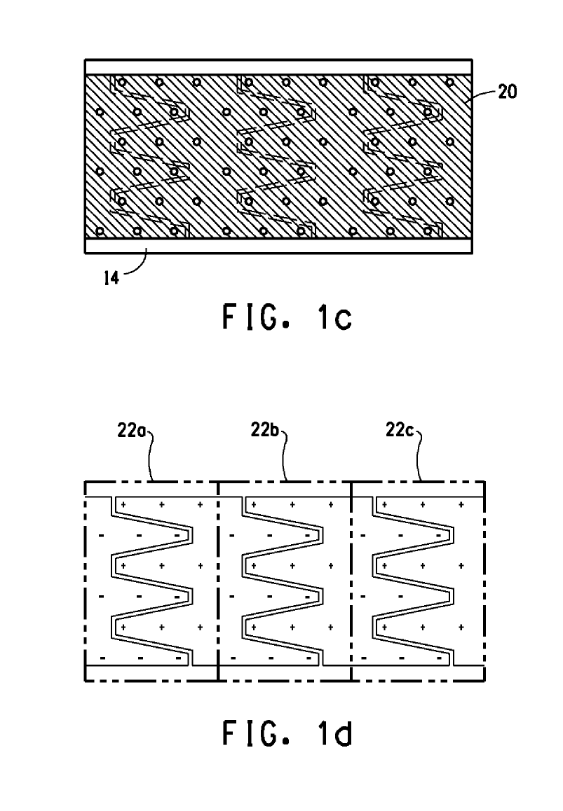

A flat die cutting press by Suzhou Tianhao electronic material Co., Ltd of Suzhou, China was used to cut through both the metal foil and tie layer adhesive film without cutting the underlying PET film. The copper foil and interlayer adhesive were die cut in a zig zag pattern like that shown in FIG. 1a using a like shaped double die cutting blade. The waste foil segments from between the die cut blades were peeled off by a rewind roll to form separated foil circuit patterns on the substrate. The PVF film/PET film/tie layer adhesive/patterned metal foil was pressed by a vacuum laminator at 140° C. for 15 min to improve the bonding strength between the metal foil and the PET film. The peeling strength between the PET film and the extruded tie layer adhesive film was determined to be about >5 N/cm. The peeling strength between the metal foil and the tie layer adhesive film was determined to be >5 N/cm.

### Example 1

The TPCu die cut circuit back-sheet described above was used to prepare an assembly for a back-contact photovoltaic module. On an extrusion-lamination machine manufactured by Davis Standard, a first 300 micron-thick EVA layer (Elvax® 1650Z resin with peroxide cross-linking agent) was extrusion coated at an extrusion temperature of 100° C. onto the copper foil like the layer 112 shown in FIG. 3a. A second 300 micron-thick EVA layer (also Elvax® 1650Z resin with peroxide cross-linking agent) was extrusion coated at an extrusion temperature of at 95° C. over the first EVA layer like the layer 114 shown in FIG. 3b. The peel strength between copper circuit the first EVA layer was 2.5 N/cm. The peel strength between the second EVA layer and the first EVA layer was 1.0 N/cm.

Die cutting was used to make a concave opening in the second EVA layer and to make electrical contact openings through the first EVA layer for registration of back contact solar cell electrical contacts. First, a flat die mold like the mold shown in FIG. 5 was used to die cut a photovoltaic cell-shape concave opening of 156×156 mm in the second EVA layer. The waste EVA was peeled from the first EVA layer to produce a concave opening like the opening 116 shown in FIG. 4. Next, a second die mold like the mold shown in FIG. 7 was used to die cut openings passing through the first EVA layer. The waste EVA die cut from the first EVA layer was peeled from the copper foil to form multiple openings like the openings 118 shown in FIG. 6. The first die cut EVA layer is able to function as the back insulating layer (i.e., both an encapsulant and inter layer dielectric (ILD) layer). EVA layer can be cross-linked during subsequent module thermoforming and assembly.

### Example 2

The TPCu die cut circuit back-sheet described above was used to prepare an assembly for a back-contact photovoltaic module as describe in Example 1. First and second EVA layers were extruded over the TPCu die cut circuit back-sheet with the same formulation and by the same process as described in Example 1.

A concave opening was formed in the second EVA layer corresponding to the shape of a back-contact solar cell, and multiple opening corresponding to the back-contact solar cell contacts were formed in the first EVA layer as shown in FIG. 6. However, the cell-shaped concave opening in the second EVA layer and the multiple electrical contact openings in the first EVA layer were die cut by a single flat die like the mold shown in FIG. 8.

### Example 3

The TPCu die cut circuit back-sheet described above was used to prepare an assembly for a back-contact photovoltaic module. On an extrusion-lamination machine manufactured by Davis Standard, a first 300 micron-thick ethylene copolymer tie layer was extrusion coated at an extrusion temperature of 260° C. onto the copper foil like the layer 112 shown in FIG. 3a. The tie layer was a 50/50 wt % blend of Bynel® 22E757 ethylene methyl acrylate copolymer and Nucrel® 0910 copolymer ethylene and methacrylic acid. A 300 micron-thick EVA layer (Elvax® 1650Z resin with peroxide cross-linking agent) was extrusion coated at an extrusion temperature of at 95° C. over the tie layer like the layer 114 shown in FIG. 3b. The peel strength between copper circuit the tie layer was 2.0 N/cm. The peel strength between the EVA layer and the tie layer was 1.5 N/cm.

Die cutting was used to make a concave opening in the EVA layer and to make electrical contact openings through the tie layer for registration of back contact solar cell electrical contacts. A single die mold like the mold shown in FIG. 8 was used to both die cut a photovoltaic cell-shape concave opening of 156×156 mm in the EVA layer, and die cut multiple openings passing through the ethylene copolymer tie layer. The waste EVA die cut from the EVA layer was peeled from the tie layer to form a back-contact cell shaped opening in the EVA layer, and the waste ethylene copolymer die cut from the tie layer was peeled from the copper foil to form multiple openings in the tie layer like the openings 118 shown in FIG. 6. The tie layer is able to function as the back insulating layer (i.e., both an encapsulant and inter layer dielectric (ILD) layer). EVA layer with cross-linking agent and tie layers without cross-linking agent for cross-linking are cross-linked during subsequent module assembly.

### Example 4

The TPCu die cut circuit back-sheet described above was used to prepare an assembly for a back-contact photovoltaic module. On an extrusion-lamination machine manufactured by Davis Standard, a first 300 micron-thick ethylene copolymer tie layer was extrusion coated at an extrusion temperature of 260° C. onto the copper foil like the layer 112 shown in FIG. 3a. The tie layer was a 50/50 wt % blend of Bynel® 22E757 ethylene methyl acrylate copolymer and Nucrel® 0910 copolymer of ethylene and methacrylic acid. A 300 micron-thick preformed EVA layer (Elvax® 1650Z resin with peroxide cross-linking agent) was laminated onto the tie layer by hot press at 65° C. for two minutes to provide an EVA layer like the layer 114 shown in FIG. 3b. The peel strength between copper circuit the tie layer was 2.0 N/cm. The peel strength between the EVA layer and the tie layer was 1.0 N/cm.

Die cutting was used to make a concave opening in the EVA layer and to make electrical contact openings through the tie layer for registration of back contact solar cell electrical contacts. A single die mold like the mold shown in FIG. 8 was used to both die cut a photovoltaic cell-shape concave opening of 156×156 mm in the EVA layer, and die cut multiple openings passing through the ethylene copolymer tie layer. The waste EVA die cut from the EVA layer was peeled from the tie layer to form a back-contact cell shaped opening in the EVA layer, and the waste ethylene copolymer die cut from the tie layer was peeled from the copper foil to form multiple openings in the tie layer like the openings 118 shown in FIG. 6. The tie layer is able to function as the back insulating layer (i.e., both an encapsulant and inter layer dielectric (ILD) layer). EVA with cross-linking agent was used in the EVA layer for cross-linking during subsequent module assembly.

### Example 5

The TPAI die cut circuit back-sheet with aluminum foil circuit as described above was used to prepare an assembly for a back-contact photovoltaic module. On an extrusion-lamination machine manufactured by Davis Standard, a first 300 micron-thick ethylene copolymer tie layer was extrusion coated at an extrusion temperature of 270° C. onto the copper foil like the layer 112 shown in FIG. 3a. The tie layer was a 50/50 wt % blend of Bynel® 22E757 ethylene methyl acrylate copolymer and Nucrel® 0910 copolymer ethylene and methacrylic acid. A 300 micron-thick preformed EVA layer (Elvax® 1650Z resin with peroxide cross-linking agent) was laminated onto the tie layer by hot press at 65° C. for two minutes to provide an EVA layer like the layer 114 shown in FIG. 3b. The peel strength between aluminum circuit and the ethylene copolymer tie layer was 2.3 N/cm. The peel strength between the EVA layer and the tie layer was 1.0 N/cm.

Die cutting was used to make a concave opening in the EVA layer and to make electrical contact openings through the tie layer for registration of back contact solar cell electrical contacts. A single die mold like the mold shown in FIG. 8 was used to both die cut a photovoltaic cell-shape concave opening of 156×156 mm in the EVA layer, and die cut multiple openings passing through the ethylene copolymer tie layer. The waste EVA die cut from the EVA layer was peeled from the tie layer to form a back-contact cell shaped opening in the EVA layer, and the waste ethylene copolymer die cut from the tie layer was peeled from the aluminum foil to form multiple openings in the tie layer like the openings 118 shown in FIG. 6. The tie layer is able to function as the back insulating layer (i.e., both an encapsulant and inter layer dielectric (ILD) layer). EVA layer with cross-linking agent and tie layers without cross-linking agent for cross-linking are cross-linked during subsequent module assembly.

What is claimed is:

1. An assembly for forming a back-contact photovoltaic module, comprising:
a substrate having back surface and a front surface;
an electrically conductive metal circuit adhered to the front surface of said substrate;
a back insulating layer having first and second opposite sides, the first side of said back insulating layer being adhered to said electrically conductive metal circuit, said back insulating layer having a plurality of openings passing through said back insulating layer that are aligned with said electrically conductive metal circuit;
a back-contact solar cell having a front light-receiving side, an opposite back side with a plurality of positive and negative polarity electrical contacts formed on said back side of said back-contact solar cell, the back side of said back-contact solar cell facing said back insulating layer, said back-contact solar cell having a side edge between the front light-receiving side and back side of the solar cell, the side edge defining a profile of the back-contact solar cell;
a front encapsulant layer having opposite first and second sides, the first side of said front encapsulant layer facing the front light-receiving side of said back-contact solar cell;
a transparent front sheet abutting the second side of said front encapsulant layer;
wherein at least one of the second side of the back insulating layer and the first side of the front encapsulant layer has a concave opening formed thereon that complements the profile of said back-contact solar cell such that the back-contact solar cell fits into the concave opening, and wherein when the back-contact solar cell is received in said concave opening, the positive and negative polarity electrical contacts formed on the back side of the back-contact solar cell align with the openings passing through said back insulating layer and with the electrically conductive metal circuit.

2. The assembly of claim 1 wherein the concave opening is on the second side of said back insulating layer.

3. The assembly of claim 2 wherein the back insulating layer is an encapsulant layer.

4. The assembly of claim 3 wherein said back insulating layer comprises a first polymer layer adhered to said electrically conductive metal circuit and a second polymer layer adhered to said first polymer layer, and wherein the peel strength between said electrically conductive metal circuit and said first polymer layer is greater than the peel strength between said first polymer layer and said second polymer layer.

5. The assembly of claim 4 wherein said concave opening is a die-cut portion of said second polymer layer that is peeled off from said first polymer layer.

6. The assembly of claim 5 wherein said plurality of openings passing through said back insulating layer are via openings die cut in said first polymer layer.

7. The assembly of claim 4 wherein said first polymer layer and said second polymer layer are a film or sheet comprising polyolefins, poly(vinyl butyral), polyurethane, polyvinylchloride, acid copolymers, silicone elastomers, epoxy resins, or a combination thereof.

8. The assembly of claim 7 wherein said first polymer layer is comprised of ethylene vinyl acetate and a cross-linking agent.

9. The assembly of claim 7 wherein said first polymer layer is an ethylene copolymer tie layer.

10. The assembly of claim 8 wherein said second polymer layer is comprised of ethylene vinyl acrylate.

11. The assembly of claim 1 wherein the concave opening is on the first side of said front encapsulant layer.

12. The assembly of claim 11 wherein said front encapsulant layer is a film or sheet comprising polyolefins, poly(vinyl butyral), polyurethane, polyvinylchloride, acid copolymers, silicone elastomers, epoxy resins, or a combination thereof.

13. The assembly of claim 11 wherein said front encapsulant layer comprises a first front encapsulant sub-layer adhered to said transparent front sheet and a second front encapsulant sub-layer adhered to said first front encapsulant sub-layer, and wherein the peel strength between said transparent front sheet and said first front encapsulant sub-layer is greater than the peel strength between said first front encapsulant sub-layer and said second front encapsulant sub-layer.

14. The assembly of claim 13 wherein said concave opening is a die-cut portion of said second front encapsulant sub-layer that is peeled off from said first front encapsulant sub-layer.

15. The assembly of claim 11 wherein said back insulating layer is a back encapsulant layer with via openings die cut in said back encapsulant layer.

16. A photovoltaic module comprising the assembly of claim 1.

17. A process for forming a back-contact photovoltaic module, comprising:
providing a substrate having a back surface and a front surface;
adhering an electrically conductive metal circuit to the front surface of said substrate;
providing a back insulating layer having first and second opposite sides, and in any order adhering the first side of said back insulating layer to said electrically conductive metal circuit, and forming a plurality of openings passing through said back insulating layer that are aligned with said electrically conductive metal circuit;
providing electrically conductive adhesive in the plurality of openings passing through said back insulating layer;
providing a back-contact solar cell having a front light-receiving side and an opposite back side with a plurality of positive and negative polarity electrical contacts formed on said back side of said back-contact solar cell, said back-contact solar cell having an exterior profile shape;
providing a front encapsulant layer having opposite first and second sides, and positioning the first side of said front encapsulant layer to face the front light-receiving side of said back-contact solar cell;
providing a transparent front sheet over the second side of said front encapsulant layer;
forming a concave opening in at least one of the second side of the back insulating layer and the first side of the front encapsulant layer which concave opening complements the exterior shape profile of said back-contact solar cell, such that the back-contact solar cell fits into the concave opening, and positioning the back-contact solar cell in said concave opening with the back side of said back-contact solar cell facing the second side of said back insulating layer so that the positive and negative polarity electrical contacts on the back side of the back-contact solar cell align with the openings passing through said back insulating layer and with the electrically conductive metal circuit;
applying heat and pressure to the transparent front sheet and the substrate to attach the front sheet and the substrate to the back-contact solar cell, and to electrically connect the positive and negative polarity electrical contacts on the back side of the back-contact solar cell to the electrically conductive metal circuit by way of the electrically conductive adhesive in the plurality of openings passing through the back insulating layer.

18. The process of claim 17 wherein the concave opening is formed in the second side of the back insulating layer.

19. The process of claim 17 wherein the concave opening is formed in the first side of the front encapsulant layer.

20. An integrated back-sheet for a back-contact photovoltaic module, comprising:
a substrate having a back surface and a front surface;
an electrically conductive metal circuit adhered to the front surface of said substrate;
a back insulating layer having first and second opposite sides, the first side of said back insulating layer being adhered to said electrically conductive metal circuit, said back insulating layer having a plurality of openings passing through said back insulating layer that are aligned with said electrically conductive metal circuit;
wherein the second side of the back insulating layer has a concave opening formed thereon that complements a profile of a back-contact solar cell such that when the back-contact solar cell is received in said concave opening, electrical contacts on the back side of the back-contact solar cell align with the openings passing through said back insulating layer and with the electrically conductive metal circuit.
